(19) United States
(12) Patent Application Publication
(10) Pub. No.: US 2025/0383300 A1
(43) Pub. Date: Dec. 18, 2025

(54) INSPECTION SYSTEM WITH GRAY LEVEL COMPENSATION AND METHOD

(71) Applicant: Taiwan Semiconductor Manufacturing Co., Ltd., Hsinchu (TW)

(72) Inventors: Yi-Zhen CHEN, Hsinchu (TW); Shang-Chieh CHIEN, Hsinchu (TW); Li-Jui CHEN, Hsinchu (TW)

(73) Assignee: Taiwan Semiconductor Manufacturing Co., Ltd., Hsinchu (TW)

(21) Appl. No.: 19/287,606

(22) Filed: Jul. 31, 2025

Related U.S. Application Data
(63) Continuation of application No. 18/404,605, filed on Jan. 4, 2024.
(60) Provisional application No. 63/581,214, filed on Sep. 7, 2023.
(60) Provisional application No. 63/614,716, filed on Dec. 26, 2023.

(51) Int. Cl. G01N 21/956; G03F 1/84; G06T 7/00

(52) U.S. Cl. CPC G01N 21/95607; G03F 1/84; G06T 7/001; G01N 2021/95676; G06T 2207/30148

(57) ABSTRACT

A method includes: generating a first image by scanning a mask; following the generating a first image, exposing the mask in a photolithography operation; following the exposing, generating a second image by scanning the mask; generating a compensated third image by performing a gray level map local compensation on the second image, the gray level map local compensation being via a transform function; generating a comparison result by comparing the compensated third image with the first image; and based on the comparison result, determining whether the mask has a defect thereon.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams depicting a system and method for inspecting a substrate and an example substrate according to embodiments of the present disclosure.

FIG. 2 is a view illustrating compensation of a gray level sampling map according to various aspects of the present disclosure.

FIG. 3 is a view illustrating compensation of a gray level distribution of a multilayer according to various aspects of the present disclosure.

FIG. 4 is a view depicting compensation of a gray level distribution of a multilayer via machine learning in accordance with various embodiments.

FIGS. 5A and 5B are views depicting detection of outliers in a gray level distribution in accordance with various embodiments.

FIG. 6 is a view depicting selection of points based on a mask design file in accordance with various embodiments.

FIG. 7 is a block diagram of a controller in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms such as “about,” “roughly,” “substantially,” and the like may be used herein for ease of description. A person having ordinary skill in the art will be able to understand and derive meanings for such terms.

Semiconductor fabrication generally involves the formation of electronic circuits by performing multiple depositions, etchings, cleanings, annealings and/or implantations of material layers, whereby a stack structure including many semiconductor devices and interconnects between is formed.

Etching is performed in many instances based on a pattern. The pattern may be first transferred to a resist layer by reflecting light from a mask that has the pattern thereon. Defects in the mask are transferred with the pattern, which can result in improper etching and malfunction of the semiconductor devices. As such, inspection of the mask is generally performed prior to using the mask in semiconductor processing. For example, a “golden” digital image of the mask without defects may be captured after the mask is fabricated. Then, prior to using the mask, another digital image may be captured and compared with the golden digital image to determine whether a defect(s) is present. In response to the defect(s) being present, the mask may be cleaned, repaired, reworked or replaced prior to beginning semiconductor processing.

One benefit of inspection is determining presence of a defect(s) on the mask front side. To achieve this, the inspection tool can compare a scan image of the mask with a golden image collected prior to EUV wafer exposure. When a mask is exposed with extreme ultraviolet (EUV) light, H-plasma and the EUV light can induce a brightness change at a surface of the mask. The brightness change of the mask resulting from the EUV exposure can induce a gray level change during inspection. This can result in false detection of defect(s) and may cause a scan failure with a large number of false positives. In some instances, a scan fail rate for a brightness/darkness (BD) scan can be as much as 2%, which can result in a reduction in tool availability of as much as 3.6 hours/week.

The brightness can change during exposure of EUV light due to contamination being removed from the surface by hydrogen plasma cleaning and EUV light. For example, prior to collecting a golden image, a new mask may be subject to hydrocarbon contamination. Photodissociation of hydrocarbons on an EUV mask surface can occur when an EUV photon is absorbed by a hydrocarbon molecule. This absorption excites the molecule to a higher electronic state, which can then dissociate into smaller fragments. The exact mechanism of photodissociation can vary based on the hydrocarbon molecule involved, but can generally include one or more of the steps described as follows. An EUV photon is absorbed by the hydrocarbon molecule, exciting it to a higher electronic state. Internal vibrational relaxation of the excited molecule occurs, which results in redistribution of the absorbed energy among different vibrational modes of the molecule. The excited molecule is then dissociated into smaller fragments. The photodissociation of hydrocarbons on the EUV mask surface can lead to a number of problems, including mask contamination, mask damage and yield loss. The dissociation fragments can deposit on the mask surface, forming a contaminant layer. This contaminant layer can absorb EUV light, reducing efficiency of the exposure process. The dissociation fragments can also damage the mask surface, leading to defects that can print onto the wafer. Both mask contamination and mask damage can lead to yield loss on the wafer.

A number of techniques have been developed to mitigate the effects of photodissociation on EUV masks, including use of low-outgassing materials, protective coatings, vacuum bakeout, laser cleaning and the like. Low-outgassing materials are less likely to release hydrocarbons that can form a contaminant layer on the mask surface. Protective coatings can be applied to the mask surface to protect it from the dissociation fragments. Vacuum bakeout can be used to remove hydrocarbons from the mask surface prior to exposure. Laser cleaning can be used to remove contaminants from the mask surface during exposure.

Light calibration may be employed to match a gray level between a scan image and a golden image. Light calibration can take two or three points on the mask as a basis to perform light calibration. Two- or three-point light calibration may not be able to compensate for local brightness of the mask, such that the brightness change resulting in scan fail cannot be mitigated sufficiently. For example, if the two or three points have measurement error, this can result in generating an unstable light calibration result. When mask scan fails due to mask brightness or gray level change, recapturing the golden image of the mask can be effective to regain calibration result stability. Namely, the new golden image can better match the current brightness or gray level of the mask. Recapturing the golden image can take 2 hours or as many as 4 hours for different types of inspection tool. In addition, the mask that fails scan may be scanned via a tool that compares the image with a mask Graphic Design System (GDS) file (e.g., a mask design), which can take as many as 12 hours for a single mask.

Embodiments of the disclosure include various beneficial features that reduce false positives due to gray level changes, resulting in an increase in tool availability. In some embodiments, to compensate for local brightness changes, a brightness map of the mask is collected prior to mask scan. By measuring gray levels at various locations distributed across the mask, local brightness information of the mask can be collected for each scan. In some embodiments, gray level compensation includes compensate via a transform equation, a machine learning model, or both. In some embodiments, in addition to or instead of collecting the spatial information of each location on the mask, a gray leveling distribution of material of the mask may be collected, which is beneficial to remove outliers of calibration points. These verification methods can also be a basis for z-map measurement error check. In some embodiments, material information from a mask GDS file is used as a basis for determining a material type associated with every location, which can be beneficial for reducing gray level compensation errors due to misjudgment of material type.

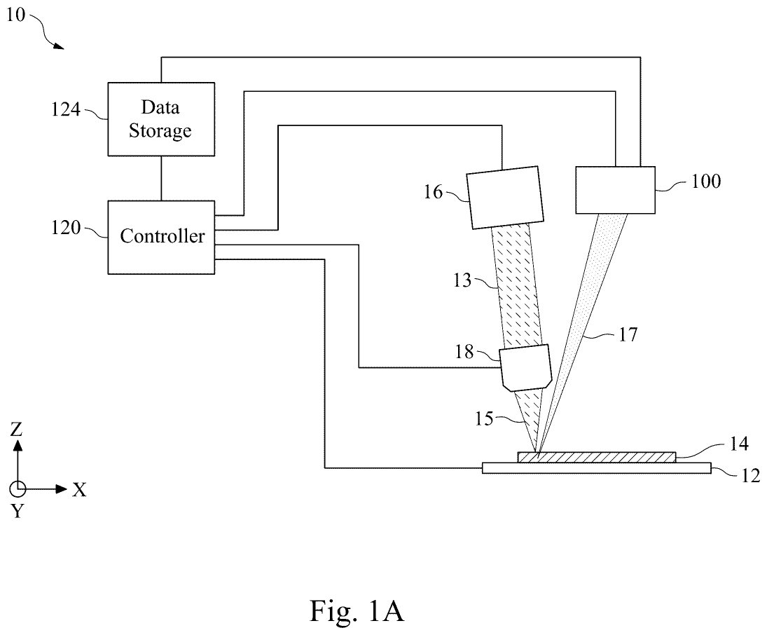

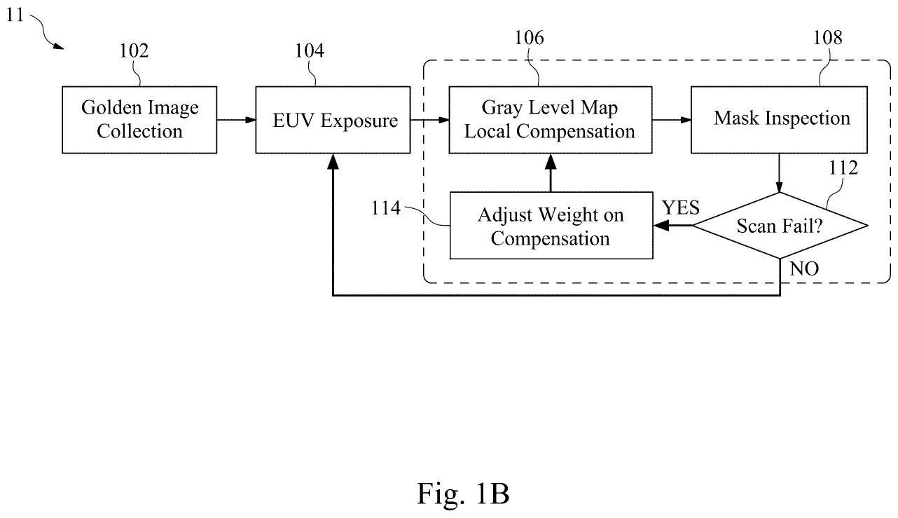

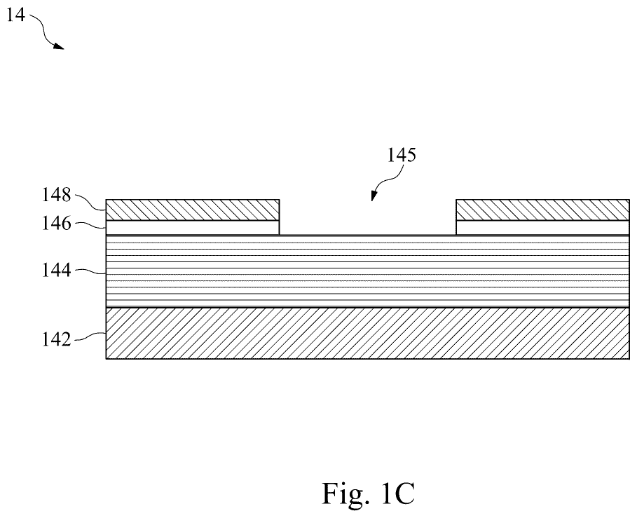

FIGS. 1A and 1B are diagrams of a system 10 and method 11 operable to inspect a substrate according to embodiments of the present disclosure. In some embodiments, the substrate is a mask, such as a mask for performing EUV photolithography.

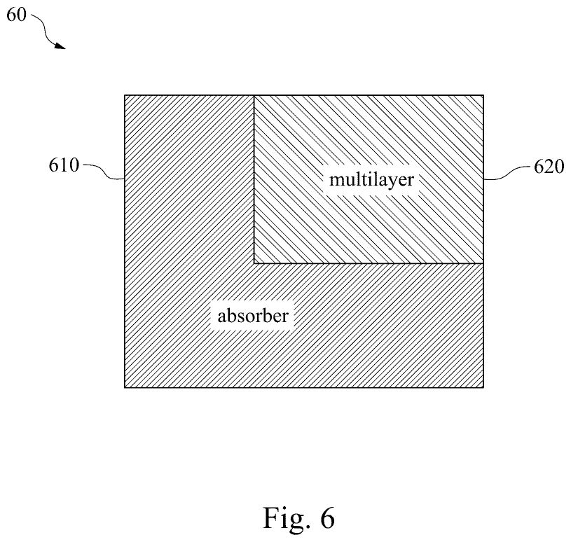

FIG. 1B is a flowchart of a method of performing sensitivity verification in accordance with various embodiments. The acts illustrated in FIG. 1B may be performed in accordance with the system 10 described with reference to FIGS. 1A, 1C and 2-6. FIG. 1B illustrates a flowchart of method 11 for performing sensitivity verification according to one or more aspects of the present disclosure. Method 11 is an example and is not intended to limit the present disclosure to what is explicitly illustrated in method 11. Additional acts can be provided before, during and after the method 11 and some acts described can be replaced, eliminated, or moved around for additional embodiments of the methods. For example, the method 11 may be used for inspecting a mask, a wafer or the like. Not all acts are described herein in detail for reasons of simplicity. Acts of method 11 are described below with reference to elements of the system 10 of FIGS. 1A, 1C and 2-6. Many of the acts may be performed by a controller 120 described with reference to FIG. 1A, an embodiment of which is a controller 60 described with reference to FIG. 6. For example, the controller 60 may execute instructions to perform the acts of method 11. It should be understood that the method 11 is not limited to being performed by the system 10 and/or the controllers 120, 60 and may be performed by systems and/or controllers that differ in one or more respects from the system 10 and/or controllers 120, 60 in other embodiments.

In FIG. 1A, a system 10 is operable to generate optical image data associated with a substrate 14 and generate an inspection result based on the optical image data. The optical image data may include an optical image of the substrate 14.

Examples of the substrate 14 include a mask for photolithography. The mask has a pattern arranged on a surface thereof. An example of a mask 14 in accordance with various embodiments is depicted in FIG. 1C.

FIG. 1C depicts a mask 14 that includes four different material layers or multilayers 142, 144, 146, 148. The layer 142 can be a substrate in some embodiments. For example, the layer 142 may be or include glass, such as fused silica or ultra-low expansion (ULE) glass. The multilayer 144 on the substrate 142 may be a reflective multilayer stack that includes alternating layers of two or more different materials, such as silicon and molybdenum. The layer 146 on the multilayer 144 may be an absorber layer that can absorb any light that is not reflected, and may include tantalum, boron nitride or the like. The layer 148 on the absorber layer 146 may be a capping layer, which can be a thin layer of material, such as ruthenium or silicon, that is deposited on top of the absorber layer to protect the mask 14 from contamination and/or oxidation. Fewer or additional layers may be included in the mask 14, such as an adhesion layer, buffer layer, anti-reflective coating (ARC) layer, etch stop layer, and the like. One or more of the layers 142, 144, 146, 148 may have a surface that is exposed. For example, openings 145 in the absorber layer 146 may expose the multilayer 144, such that light incident on the multilayer 144 may be reflected while light incident on the absorber layer 146 may be absorbed. In this way, the openings 145 of the mask 14 can form a pattern, which may be used to expose a photoresist layer on a wafer during a photolithography operation.

In FIG. 1A, optical image data corresponding to the pattern may be generated, for example, by a sensor or detector 100. A controller 120 may detect a defect of the pattern of the mask by comparing golden or reference image data generated via a golden or reference image generation function with the optical image data outputted by the detector 100.

The system 10 includes a stage 12 that can be translated in one or more horizontal directions (e.g., an X-axis direction and a Y-axis direction) and a third direction, which may be a vertical direction (e.g., a Z-axis direction) or a rotational direction (e.g., a θ-axis direction). The system 10 may include a monitoring apparatus that determines a position of the stage 12. They system 10 includes a light source 16 that generates light 13 of a selected wavelength, such as an EUV wavelength (e.g., 13.5 nanometers). The system 10 includes illumination optics 18 that direct and/or collect light 13 from the light source 16, such that light 15 may impinge on the mask 14. An imaging device 100 generates the optical image data associated with the mask 14. The system 10 may include a loader, which may have a robot arm, that is operable to position the mask 14 on the stage 12 and/or remove the mask 14 from the stage 12.

The system may include one or more controllers 120 that can control various operations of the system 10. The controller 120 may be in data communication with the detector 100, the light source 16, the illumination optics 18 and the stage 12.

The light source 16 may be operable to generate light 13 of a single wavelength ω, such as a laser, and may be a laser light source 16. Output wavelength range of the light source 16 may be in a wavelength domain, such as a visible light domain, an ultraviolet (UV) domain, a middle ultraviolet (MUV) domain, a deep ultraviolet (DUV) domain, an extreme ultraviolet (EUV) domain or the like. The light source 16 may include a visible domain laser, such as a helium-neon laser, an argon laser, a krypton laser, or the like. In some embodiments, the light source 16 includes an excimer laser, a helium-cadmium laser, a nitrogen laser, an argon fluoride laser, a krypton fluoride laser, a free-electron laser or the like.

The detector 100 may include an imaging device and/or a photodiode. The controller 120 may be operable to calibrate or select parameters of the imaging device, which may include a charge-coupled device (CCD) imaging device or complementary metal-oxide semiconductor (CMOS) imaging device. The CCD imaging device and the CMOS imaging device may each be a time delay integration (TDI) imaging device. In some embodiments, the controller 120 includes a microcontroller unit (MCU), processor, multiprocessor, or the like. The controller 120 may be in data communication with the detector 100 for selecting parameters thereof.

Various parameters of CCD, CMOS, TDI CCD, and TDI CMOS sensors may be controlled in real-time via, for example, an MCU, such as the controller 120. Gain of the sensor can control how much the signal from each pixel of the detector 100 is amplified. Increasing the gain can improve the sensitivity of the detector 100 but can also increase noise. The offset of the detector 100 controls the black level of the image. Increasing the offset can reduce the noise in the image but can also make it more difficult to detect small defects in the mask. The integration time can refer to amount of time that the detector 100 is exposed to light. Increasing the integration time can improve signal-to-noise ratio (SNR) of the image but can also make the detector 100 more susceptible to motion blur. The detector 100 can be triggered to start and stop integration in real-time, which can be beneficial to synchronize the detector 100 with the mask scanner or other devices in the inspection system.

In addition to these parameters, some detectors 100 may also allow for real-time control of other features, such as the number of TDI stages or the shift frequency. The parameters that can be controlled or selected in real-time can vary depending on the detector 100 and the MCU. Selection of the various parameters or characteristics may be performed by the controller 120, in some embodiments.

Following are examples of how real-time control or selection of sensor parameters can be used in semiconductor mask inspection. The gain of the detector 100 can be adjusted to compensate for changes in lighting conditions. The offset of the detector 100 can be adjusted to compensate for changes in the background noise level. The integration time of the detector 100 can be adjusted to improve the SNR for different mask features. The detector 100 can be triggered to start and stop integration at selected points in the mask scanning process, which can be beneficial to synchronize the detector 100 with the mask scanner or to capture images of selected regions on the mask.

The CCD, CMOS, TDI CCD, and/or TDI CMOS sensors may include various characteristics that are beneficial to semiconductor mask inspection. For example, a CCD sensor may have characteristics, such as pixel size, well depth and readout noise. A smaller size of each pixel on the detector 100 may be beneficial for higher resolution images but can also result in more noise. Well depth can refer to a maximum number of photoelectrons that a pixel can hold before it saturates, which can be beneficial for low-light imaging and imaging high-contrast scenes. Readout noise can refer to amount of noise that is introduced into an image during a readout process. Reducing readout noise may be beneficial for low-light imaging and for imaging scenes with high dynamic range.

For a CMOS sensor, pixel size, fill factor and dark current may be characteristics that are beneficial to semiconductor mask inspection. As described previously, smaller pixels may allow for higher resolution images but can also result in more noise. Fill factor can refer to percentage of the pixel area that is sensitive to light. A higher fill factor can result in a higher sensitivity detector 100. Dark current can refer to an amount of current that flows through the CMOS sensor even when it is not exposed to light. Dark current reduction can be beneficial for low-light imaging and for imaging scenes with high dynamic range.

In a TDI CCD sensor, characteristics that can be beneficial may include number of stages and shift frequency. The number of stages is associated with number of times that image charge packets are shifted along rows of the CCD sensor. A higher number of stages can result in a higher signal-to-noise ratio (SNR) image. Shift frequency can refer to frequency at which the image charge packets are shifted along the rows of the CCD sensor. Matching the shift frequency to speed of the object being imaged (e.g., the mask) is beneficial to improve imaging quality.

In a TDI CMOS sensor, number of stages, shift frequency and rolling shutter may be characteristics that are beneficial in one or more ways to mask inspection. CMOS sensors can use a rolling shutter, which refers to the detector 100 being read out one row at a time. The rolling shutter can result in image distortion when the object being imaged (e.g., the mask) is moving. TDI CMOS sensors can include a global shutter, which reads out the entire detector 100 at once. This can be beneficial to reduce or eliminate image distortion but may increase cost and/or complexity of the CMOS sensor.

In the context of semiconductor mask inspection, the following characteristics may be particularly beneficial: pixel size, well depth, readout noise, number of TDI stages, shift frequency, rolling shutter and integration time. The pixel size can be selected to be small enough to resolve the features on the mask. The well depth can be selected to be high enough to avoid saturating the pixels when imaging bright features on the mask. The readout noise can be selected to be low enough to avoid obscuring small defects on the mask. The number of stages can be selected to be high enough to achieve the selected SNR. The shift frequency can be selected to be matched to the speed of the mask scanner. A global shutter may be selected to avoid image distortion. Semiconductor mask inspection can be performed in low-light conditions, such that detectors 100 with long integration times may be beneficially selected. Selection of the various parameters or characteristics may be performed by the controller 120, in some embodiments.

One or more of the controller 120 and the detector 100 may be in data communication with a data storage device or system 124, which may be a database, server, data center, or the like. The data storage device 124 may store digital data generated by the controller 120, the detector 100, external devices, combinations thereof or the like. For example, the digital data may include one or more of a recipe, golden or reference images, inspection images, sensor data (other than from the detector 100), combinations thereof and the like. The digital data may include one or more inspection algorithms, which may be used by the system 10 to inspect the mask 14 and may include defect detection algorithms. The digital data may include one or more mask designs or design files (e.g., GDS files), which may include reference designs and mask patterns that can be compared against the mask 14 being inspected. The digital data may include historical inspection data, which may include past inspection results, including detected anomalies or defects. The digital data may include one or more inspection settings, such as parameters and/or configurations for different types of masks, inspection modes or other hardware settings. The digital data may include inspection reports, which can be detailed reports that include metrics, detected defects, and images or scans from the inspections. The digital data may include system logs, which may be related to system performance, errors and other events of the system 10. The digital data may include calibration data, which may be or include data related to calibration of various hardware components, such as the detector 100 and light source 16. The digital data may include equipment status data, such as information associated with state of various system components, including, for example, predictive/periodic maintenance data. Other data included in the digital data may include vendor and part information, such as details about hardware components, vendors thereof, firmware versions thereof, and the like. Quality control data may be stored as digital data, including information related to quality control procedures that the mask 14 may undergo, as well as results from the quality control procedures. Job queues, such as schedules and/or queues for upcoming inspections may be stored as digital data in the data storage system 124. The data storage system 124 may store raw data, such as raw data that is collected by the detector 100 during the inspection. Additional or fewer data may be stored in and by the data storage system 124.

The digital data of the data storage system 124 may be accessible by the controller(s) 120. The controller 120 may store at least some of digital data to the data storage system 124 and may receive at least some of digital data from the data storage system 124. For example, the controller 120 may receive a recipe from the data storage system 124 and may control operation of the stage 12, the light source 16 and the detector 100 based on the recipe. In another example, the controller 120 may receive a historical or reference or golden image and an inspection image from the data storage system 124 and may compare the images to determine presence or absence of defects in the mask 14. The controller 120 may generate a comparison result based on the comparison, and may store the comparison result in the data storage system 124.

FIG. 1B depicts a flowchart of a method 11 for inspecting a substrate (e.g., a mask) in accordance with various embodiments.

The method 11 begins with act 102, which includes collecting one or more golden or reference images associated with one or more respective masks. In the context of mask inspection, the “golden” image can be a reference image of a perfect (or near perfect) mask. The golden image is used to compare with images of actual masks to identify any defects. The golden images may be generated by imaging a mask that is known to produce high-quality wafers. The golden image can be taken under the same or similar conditions as images of actual masks that will be inspected. For example, the same illumination source 16, optics 18 and detector 100 can be used. Once the golden image has been created, it can be used to inspect actual masks for defects. Differences between the golden image and the image of the actual mask can indicate a defect.

Act 104 follows act 102. In act 104, the mask 14 is exposed via ultraviolet light (e.g., EUV light), which may be during wafer processing, such as a photolithography process. In EUV lithography, the mask or photomask 14 is used to transfer a circuit pattern onto a semiconductor wafer. Prior to the photolithography process, the mask 14 may be cleaned to remove any particles or contaminants. The mask may then be loaded into an EUV scanner and aligned to ensure the pattern will be accurately transferred. A laser-produced plasma (LLP) source then generates EUV light. Collector mirrors focus and direct the light towards the mask 14. The EUV light illuminates the mask 14. The mask 14 contains patterns made from materials that alternately absorb or reflect the EUV light. The light that is reflected by the mask 14 carries the pattern information. The patterned EUV light is then projected onto a photoresist-coated semiconductor wafer, which can be done through a series of lenses known as projection optics or a projection optics box (POB). In most instances, features of the mask 14 are demagnified by the projection optics, such as by a factor of 4 to 5, to accurately project the extremely small features onto the wafer.

After exposure, the mask 14 may be inspected for defects or particle contamination that may have occurred during the process, so as to increase quality of future wafer exposures. Inspection is described in greater detail with reference to acts 106, 108, 112, 114, which are highlighted in FIG. 1B by a dashed line box. Metrics related to performance and accuracy of the mask 14 may be collected and may be sent to the database 124 for analysis by the controller 120 or another analysis system. Once the exposure cycle is complete and the mask 14 has been inspected and cleaned, the mask 14 may be returned to a protective environment to reduce contamination risk.

Act 106 follows act 104. Act 106 includes collecting and/or generating a gray level map associated with the mask 14, and may include performing local compensation of the collected or generated gray level map. To compensate for local brightness changes, a brightness or gray level map of the mask 14 may be collected or generated prior to scanning the mask 14. By measuring gray levels or brightness levels distributed over the entire mask 14 or most of the mask 14, local brightness information of the EUV mask 14 may be generated for each scan.

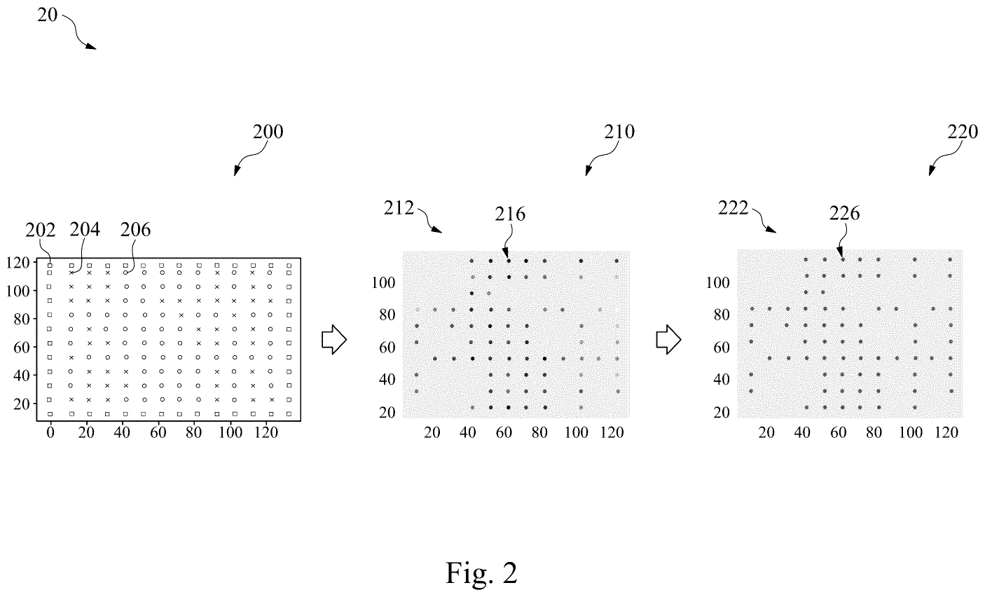

FIG. 2 depicts an example of sampling points of a gray level map of the mask 14. Sampling the points may be performed via operations 200, 210, 220, which are described in detail in the following.

Operation 200 is an example of sampling points 202, 204, 206 of a gray level map. Each point on the map has z-height value and gray level value. For example, first points 202 are associated with a border (or “black border”) region of the mask 14, second points 204 are associated with absorber regions of the mask 14 and third points 206 are associated with multilayer regions of the mask 14. The absorber regions may be regions of the mask 14 in which the absorber layer 146 is present. The multilayer regions may be regions of the mask 14 in which the openings 145 are present and expose the multilayer 144. In operation 200, materials of the mask 14 may be classified or identified based on z-axis height at each location. For example, height of the absorber regions may exceed height of the multilayer regions, as depicted in FIG. 1C.

In operation 202, which follows operation 200, a target gray level of each material may be calculated based on the gray level distribution of each material. In some embodiments, an average of the gray levels of each material is calculated. In the example depicted in FIG. 2, a gray level map 212 may be generated that only includes gray levels 216 of the third points 206 associated with the multilayer region of the mask 14. Some of the gray levels 216 may exceed the average of the gray levels, while others of the gray levels 216 may not exceed (e.g., may be below) the average of the gray levels. The target gray level may be the average, in some embodiments, however another gray level that exceeds or is less than the average may be used as the target gray level in other embodiments. The gray level map 212 may also be referred to as a first or pre-compensation gray level map 212.

In operation 204, which follows operation 202, a second gray level map 222 may be generated in which each point on the map 222 has been compensated. For example, the second gray level map 222 may include compensated gray levels 226 of the third points 206. In some embodiments, the compensated gray levels 226 have the same values as each other, such as the target gray level (e.g., the average). In some embodiments, the compensated gray levels 226 have values that are in a range that is smaller than a range of the gray levels 216. For example, a first range of gray level values of the gray levels 216 may exceed a second range of gray level values of the compensated gray levels 226 by a factor that exceeds about 2, about 3, about 4, about 5 or another suitable factor. Namely, the second range may be about half the size of the first range or less. In some embodiments, generation of the compensated gray levels 226 is by machine learning, such as based on a trained neural network.

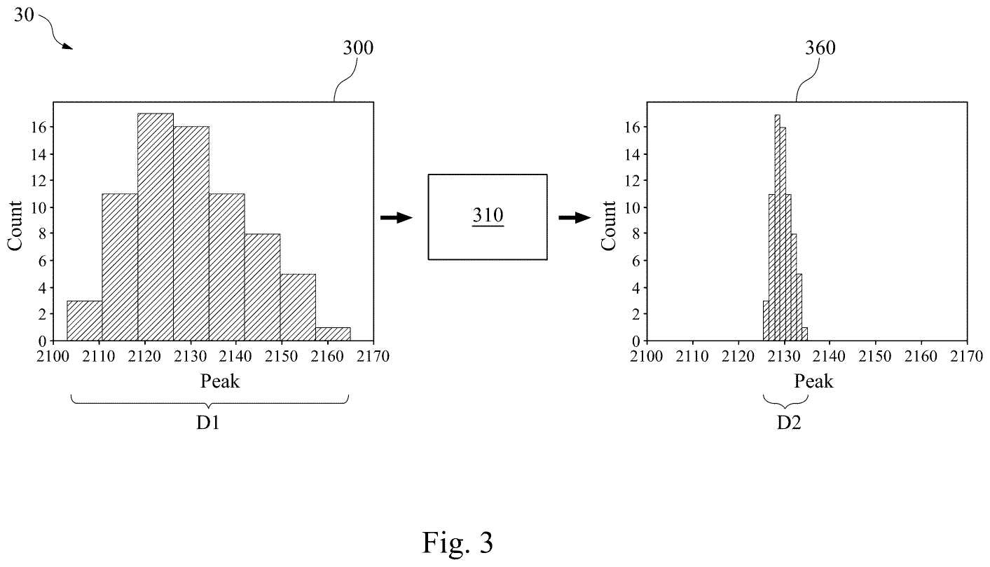

FIG. 3 is a diagram that depicts a process 30 for performing compensation of gray levels in accordance with various embodiments. The process 30 may be an embodiment of the operations 202, 204 described with reference to FIG. 2.

In the process 30, a first gray level map 300 may represent a histogram of gray level values of the gray level map 212 of FIG. 2. The first gray level map 300 may be referred to as a pre-compensation gray level map. A vertical axis of the first gray level map 300 may represent count or number of third points 206 associated with a gray level or narrow range of gray levels. A horizontal axis of the first gray level map 300 may represent a gray level value associated with each bar of the first gray level map 300. As depicted in FIG. 3, prior to compensation, a range of the gray levels of the first gray level map 300 may have a dimension D1, such as about 60 levels, which may be centered around a first gray level, such as about 2130.

A transform function 310 may be applied to the first gray level map 300 to generate a second gray level map 360. The second gray level map 360 may be referred to as a post-compensation gray level map 360. A range of the gray levels of the second gray level map 360 post compensation may have a dimension D2, such as about 10 levels, which may be centered around a second gray level, such as about 2130. The second gray level and the first gray level may be the same as each other or different from each other. In the example of FIG. 3, the first and second gray levels are about the same as each other.

In some embodiments, the transform function 310 may be

$$\frac{GL - {GL}_{mean}}{{GL}_{std} \cdot k} + {GL}_{mean} = {GL}_{new} .$$

In the transform function 310, each pre-compensation individual gray level may be represented by “GL,” and “GLₘₑₐₙ” may refer to the average gray level, “GL_{std}” may refer to a standard deviation of the pre-compensation histogram, “k” may be a compensation factor and “GL_{new}” may refer to a post-compensation individual gray level. Increasing compensation factor k reduces the size of the dimension D2. In some embodiments, the compensation factor k is selected based on scan performance.

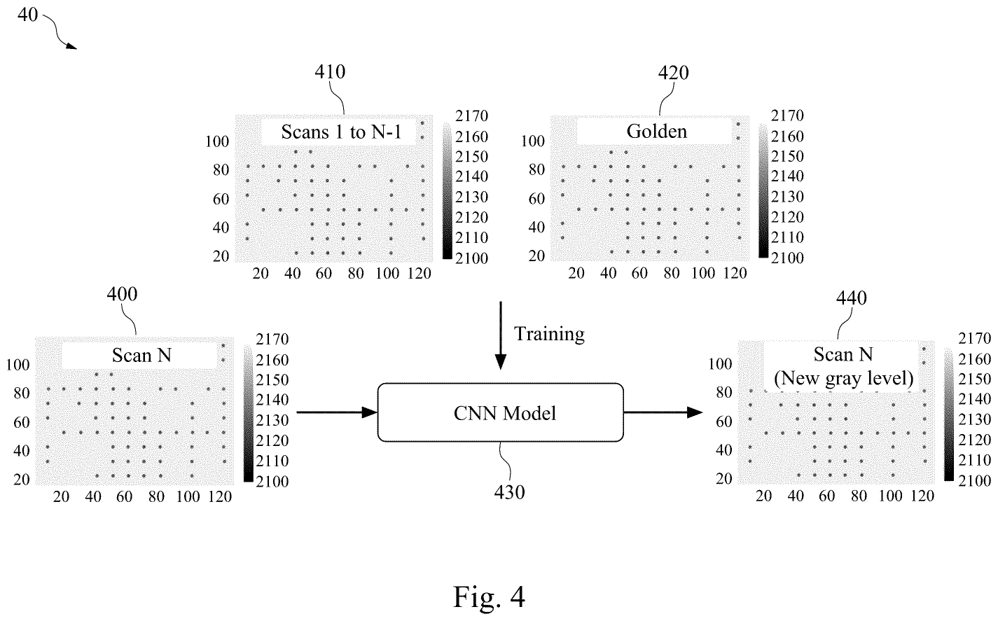

FIG. 4 is a diagram that depicts a process 40 for performing compensation of gray levels in accordance with various embodiments. The process 40 may be an embodiment of the operations 202, 204 described with reference to FIG. 2.

In the process 40, gray level compensation may be performed via machine learning, such as based on a trained neural network. The gray levels of the mask 14 may gradually change due to repeated exposure of EUV light. A model including a convolutional neural network (CNN) may be trained based on gray level distributions of historical scans and a golden or reference scan. In some embodiments, the model is operable to match gray levels of a new scan with gray levels of a golden or reference scan.

As depicted in FIG. 4, a CNN model 430 may be trained based on training data, which can include historical scans 410 and a golden or reference scan 420. In some embodiments, the historical scans 410 and golden scan 420 are for a single mask, such as the mask 14. In some embodiments, the historical scans 410 and golden scan(s) 420 are for a large number of masks, which can include the mask 14. In embodiments in which the CNN model 430 is trained on a large number of masks, the historical scans 410 and the respective golden scan 420 may be associated with each other. The CNN model 430 may also be referred to as a trained CNN model 430. The trained CNN model 430 may be used to compensate gray levels of a new scan 400 to generate a compensated new scan 440. The new scan may be an embodiment of the first gray level map 212 depicted in FIG. 2 and the compensated new scan 440 may be an embodiment of the second gray level map 212 depicted in FIG. 2.

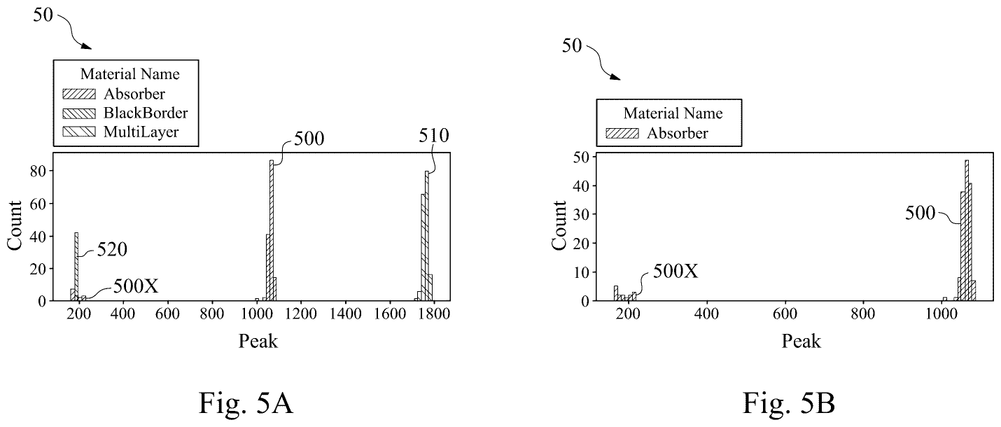

FIGS. 5A and 5B depict histograms or maps 50. The histogram 50 of FIG. 5A includes gray levels 500, 510, 520 for more than one material, such as absorber gray levels 500, black border gray levels 520 and multilayer gray levels 510. The histogram 50 of FIG. 5B depicts only absorber gray levels 500 and outliers thereof 500X. In addition to the spatial information of each point, a gray level distribution of each material of the mask 14 may be determined, which can be beneficial to remove or repair outliers of calibration points. Such a verification method can also be beneficial for improving z-map measurement error checks.

FIG. 5A depicts intensity distributions of all materials, where each material can have different gray levels 500, 510, 520. In some instances, one or more points or outliers 500X can be identified as an incorrect material due to defocusing during measurement of the z-axis height. Another reason for incorrect identification can be that a single point may be positioned at a boundary of two different materials, such that both materials are measured for the single point. After determining an intensity distribution of each material, outliers of each material may be detected relatively easily. FIG. 5B depicts an example of the outliers 500X of absorber gray levels 500. For the outlier points 500X, the points 500X may be resampled and correct z-axis heights of the points 500X may be determined. As such, the gray level distribution of each material can be a basis for a method of measurement verification.

FIG. 6 depicts an example of a point 60 that includes multiple materials 610, 620. In the example of FIG. 6, the point 60 can include both an absorber material region 610 and an adjacent multilayer material region 620. Identifying the material of each location based on z-axis height may suffer from measurement fluctuations, which can induce erroneous identification. Even though some incorrectly identified points can be rejected based on the distribution of gray levels of each material as described with reference to FIGS. 5A and 5B, an additional or alternative method to avoid this kind of error is based on a mask design file (e.g., a GDS file), which contains pattern information of each point on the mask 14. Based on information in the GDS file, the method 11 can avoid measuring points containing multiple materials and can avoid wrong pattern identification induced by measurement errors. For example, for one or more points, such as the point 60, each of which includes two or more regions associated with different materials, the points can be excluded from the gray level map local compensation operation 106.

Returning to FIG. 1B, act 108 follows act 106. In act 108, the mask is inspected. For example, the mask 14 may be inspected in act 108. When the mask 14 has been exposed repeatedly to extreme ultraviolet (EUV) light (e.g., during wafer exposure), H-plasma and the EUV light can induce a brightness change at a surface of the mask 14. The brightness change of the mask 14 resulting from the EUV exposure can induce a gray level change that is picked up by the detector 100 during inspection. This can result in false detection of defect(s) and may cause a scan failure with a large number of false positives. In some instances, a scan fail rate for a brightness/darkness (BD) scan can be as much as 2%, which can result in a reduction in tool availability of as much as 3.6 hours/week.

The mask inspection in act 108 may include various operations. Initially, the mask 14 may be loaded into the inspection system 10, which may be in a controlled environment to reduce the risk of contamination. The mask 14 may be placed on the stage 12 when loaded into the system 10. Prior to the inspection starting, the mask 14 may be precisely aligned within the system 10. Then, the mask 14 may be illuminated for the purpose of inspection. Various light sources, such as the light source 16, can be used for the inspection. The mask 14 may be scanned by moving it relative to the focused light source 15 via the stage 12, or by moving the light source 16 and optics 18 relative to the mask. As the mask 14 is scanned, the light 17 reflected by the mask 14 is collected by detector(s) 100 as data. The data can be compared to an expected pattern based, for example, on design data of the mask 14. Any variations between the captured data and the expected pattern may be flagged as potential defects. These can include particle contamination, pinholes, scratches, or issues with the pattern itself like missing or misshaped features. The identified defects can be stored as digital data based on type and size, which can be beneficial in determining whether the mask 14 is suitable for use or whether to repair or replace the mask 14. As mentioned previously, brightness changes of the mask 14 resulting from the EUV exposure can induce a gray level change that is picked up by the detector 100 as a defect during inspection. This can result in false detection of defect(s) and may cause a scan failure with a large number of false positives.

Act 112 follows act 108. In act 112, a determination is made whether the mask failed the inspection scan. In response to the mask 14 not failing the inspection scan, the mask 14 may be used in another exposure operation 104 to pattern a photoresist layer on a wafer. Prior to returning to the lithography system, the mask 14 may be cleaned to remove any contaminants that may have landed on the mask 14 during the inspection process 108. In response to the mask 14 failing the inspection scan, the method 11 may proceed to act 114.

Act 114 follows act 112. In act 114, a weight of the compensation is adjusted. In some embodiments, the weight of the compensation refers to the compensation factor k described with reference to FIG. 3. As described previously, a transform function 310 may be applied to the first gray level map 300 to generate the second gray level map 360. In some embodiments, the transform function 310 may be

$$\frac{GL - {GL}_{mean}}{{GL}_{std} \cdot k} + {GL}_{mean} = {GL}_{new} .$$

When the scan of the mask 14 fails in the inspection of act 108, the failure may be due to insufficient compensation of the gray levels of the first gray level map 300 in act 106. As such, the first gray level map 300 or the second gray level map 360 may undergo another compensation in act 114. For example, in act 106, prior to performing act 108 for the first time, the second gray level map 360 may be generated based on the compensation factor k being a first value (e.g., 2). After the inspection of act 108 fails, the second gray level map 360 may be regenerated in act 106 using a new, second value for the compensation factor k that exceeds the first value (e.g., 3). The second value may be selected in act 112. Selection of the second value of the compensation factor k may be via the controller 120, and may be based on an algorithm. For example, the controller 120 may select the second value by increasing the compensation factor k by one. In another example, the controller 120 may select the second value by increasing the compensation factor k by a percentage, such as 5%, 10%, or another suitable percentage. Namely, the first value may be 2 and the second value may be 2.1 or 2.2, in one example. Increasing the compensation factor k is beneficial to tighten the histogram of the gray level distribution, which can reduce the occurrence of false positive defect detections due to the brightness change of the mask 14 due to repeated EUV exposure.

In some embodiments, the gray levels of the second gray level map 360 are initially generated via the trained neural network. In these embodiments, after the inspection scan fails, the second gray level map 360 may undergo the transform function 310 to generate a third gray level map 360 having narrower gray level distribution. Namely, the weight adjustment of act 114 can be of a different type than the initial compensation performed in act 106.

As depicted in FIG. 1B, the acts 106, 108, 112, 114 may be repeated until the inspection scan in act 108 passes. In some embodiments, adjusting the weight of the compensation in act 114 may be performed based on a threshold value associated with number of defects detected on the mask 14. For example, a brightness change of the mask 14 may be expected to result in a large number of false positive defect detections in a single inspection scan due to the brightness change being substantially a global phenomenon. As such, when a number of defect detections does not exceed a threshold value, a determination may be made to rework, repair or replace the mask 14 due to actual defects being present on the surface thereof. When the number of defect detections does exceed the threshold value, a determination may be made to proceed to act 114 to adjust the gray level distribution via increasing the compensation factor k.

By adjusting the gray value distribution prior to performing the mask inspection, compensation for local brightness changes due to repeated EUV exposure may be accomplished, which is beneficial to reducing false positives, and increasing tool availability.

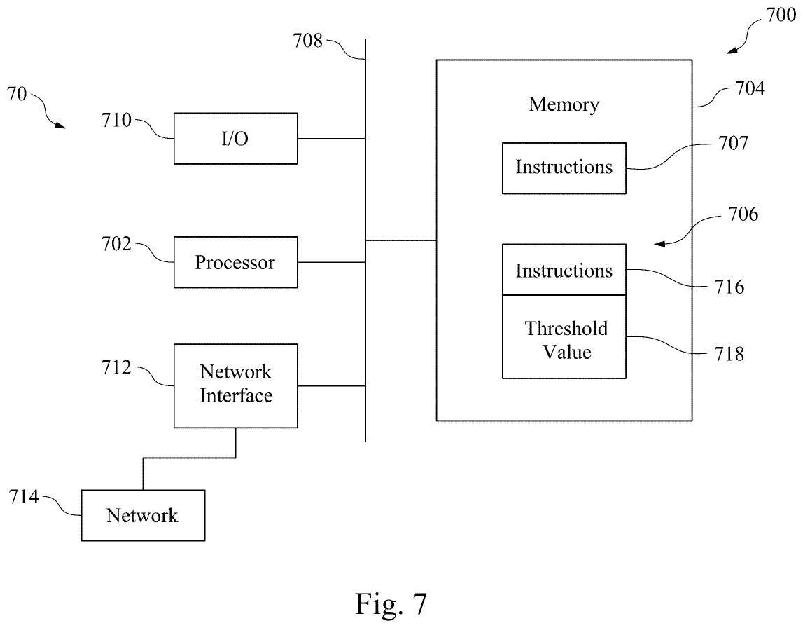

FIG. 7 is a schematic view of a controller 70 in accordance with various embodiments. The controller 70 may be an embodiment of the controller 120 described with reference to FIG. 1A. The controller 70 may perform operations described with reference to FIGS. 1A-6. The controller 70 is described with reference to the system 10 and the method 11.

In FIG. 7, the controller or control system 70 includes a processor 702, a memory 700, a data interface 710 and a network interface 712. Some elements of the controller 70 may be omitted from view for simplicity of illustration. For example, the controller 70 may include a power supply (e.g., voltage regulator), analog-to-digital converters (ADCs), digital-to-analog converters (DACs), pulse width modulation (PWM) controller, clocks and timing circuitry, and the like.

The control system 70 generates output control signals for controlling operation of one or more components of the system 10. The control system 70 may receive input signals from one or more components of the system 10.

Control system 70 includes a processor 702 and a non-transitory, computer readable storage medium 704 encoded with, i.e., storing, computer program code 706, i.e., a set of executable instructions. Computer readable storage medium 704 is also encoded with instructions 707 for interfacing with components of system 10. The processor 702 is electrically coupled to the computer readable storage medium 704 via a bus 708. The processor 702 is also electrically coupled to an I/O interface 710 by bus 708. A network interface 712 is also electrically connected to the processor 702 via bus 708. Network interface 712 is connected to a network 714, so that processor 702 and computer readable storage medium 704 are capable of connecting to external elements via network 714. The processor 702 is configured to execute the computer program code 706 encoded in the computer readable storage medium 704 in order to cause control system 70 to be usable for performing a portion or all of the operations as described with respect to system 10.

In some embodiments, the processor 702 is a central processing unit (CPU), a multi-processor, a distributed processing system, an application specific integrated circuit (ASIC), and/or a suitable processing unit.

In some embodiments, the computer readable storage medium 704 is an electronic, magnetic, optical, electromagnetic, infrared, and/or a semiconductor system (or apparatus or device). For example, the computer readable storage medium 704 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 704 includes a compact disk-read only memory (CD-ROM), a compact disk-read/write (CD-R/W), and/or a digital video disc (DVD).

In some embodiments, the storage medium 704 stores the computer program code 706 configured to cause control system 70 to perform the operations as described with respect to system 10 and method 11. In some embodiments, the storage medium 704 also stores information needed for performing the operations as described with respect to system 10 and method 11, such as a set of executable instructions to perform the operations as described with respect to system 10 and method 11. In some embodiments, the storage medium 704 stores the trained neural network 430 described with reference to FIG. 4.

In some embodiments, the storage medium 704 stores instructions 707 for interfacing with system 10. The instructions 707 enable processor 702 to generate operating instructions readable by elements of the system 10 to effectively implement the operations as described with respect to system 10 and method 11.

Control system 70 includes I/O interface 710. I/O interface 710 is coupled to external circuitry. In some embodiments, I/O interface 710 includes a keyboard, keypad, mouse, trackball, trackpad, and/or cursor direction keys for communicating information and commands to processor 702.

Control system 70 also includes network interface 712 coupled to the processor 702. Network interface 712 allows control system 70 to communicate with network 714, to which one or more other computer systems are connected. Network interface 712 includes wireless network interfaces such as BLUETOOTH, WIFI, WIMAX, GPRS, or WCDMA; or wired network interface such as ETHERNET, USB, or IEEE-1394.

Control system 70 may be configured to receive information related to the gray level maps and/or distributions and the GDS files through I/O interface 710. The information is transferred to processor 702 via bus 708 and then stored in computer readable medium 704 as parameters 716. Control system 70 can be configured to receive information related to a threshold value through I/O interface 710. In some embodiments, the threshold value is received from an operator. The information is stored in computer readable medium 704 as threshold value parameter 718. For example, the threshold value parameter 718 may be associated with number of defects detected in a single scan. In one example, a number of defects detected in act 108 may be compared with the threshold value parameter 718, and a determination may be made whether to adjust one or more parameters of the gray level map 300.

During operation, in some embodiments, processor 702 executes a set of instructions to determine whether the number of defects detected has exceeded or is below a threshold value. Based on the above determinations, processor 702 generates a control signal to instruct one or more components of the system 10 to adjust a parameter thereof. In some embodiments, the control signal is transmitted using I/O interface 710. In some embodiments, the control signal is transmitted using network interface 1012. In some embodiments, the control signal is used internally by the processor 702 to trigger execution of act 114 to adjust compensation weight of the first or second gray level map 300, 360.

Embodiments may provide advantages. By adjusting weight of compensation of a gray level map or distribution thereof, false positive defect detections due to a brightness change in a mask exposed repeatedly to EUV light may be reduced. Reducing the number of false positive defect detections can save downtime related to repairing and/or replacing the mask, which increases tool availability.

In accordance with at least one embodiment, a method includes: generating a first image by scanning a mask; following the generating a first image, exposing the mask in a photolithography operation; following the exposing, generating a second image by scanning the mask; generating a compensated third image by performing a gray level map local compensation on the second image, the gray level map local compensation being via a transform function; generating a comparison result by comparing the compensated third image with the first image; and based on the comparison result, determining whether the mask has a defect thereon.

In accordance with at least one embodiment, a method includes: generating a reference image by scanning a mask; following the generating a reference image, generating a second image by scanning the mask; generating a third image by performing a gray level map local compensation on the second image, the gray level map local compensation being via a trained neural network; generating a comparison result by comparing the third image with the first image; and based on the comparison result, determining whether the mask has a defect thereon.

In accordance with at least one embodiment, a system includes: a light source; a mask stage operable to position a mask in an optical path of light generated by the light source; a detector operable to generate a second image by scanning a mask on the mask stage, the mask having been exposed to extreme ultraviolet (EUV) light in a lithography system prior to the scanning a mask; and a controller including: a memory that stores computer instructions; and a processor configured to execute the computer instructions to: generate a compensated third image by performing a gray level map local compensation on the second image; generate a comparison result by comparing the compensated third image with a reference image of the mask; and based on the comparison result, determine whether the mask has a defect thereon.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
illuminating a mask with a light source, the mask being known to produce high-quality semiconductor wafers;
generating a first image by scanning the mask;
following the cleaning, exposing the mask in a photolithography operation;
following the exposing, generating a second image by scanning the mask;
generating a compensated third image by performing a first gray level map local compensation on the second image;
generating a comparison result by comparing the compensated third image with the first image; and
based on the comparison result, determining whether the mask has a defect thereon.

2. The method of claim 1, wherein the first gray level map local compensation is via a transform function, and the generating a compensated third image is via the transform function that is
$$\frac{GL - {GL}_{mean}}{{GL}_{std} \cdot k} + {GL}_{mean} = {GL}_{new} ,$$
GL being a gray level at a position in the second image, GLₘₑₐₙ being an average of a plurality of gray levels at a plurality of positions in the second image, GL_{std} being a standard deviation of the plurality of gray levels, GL_{new} being a compensated gray level and k being a compensation factor, the compensation factor being at least 1.

3. The method of claim 2, wherein the compensation factor exceeds about 2.

4. The method of claim 1, further comprising, in response to determining that the mask has a defect thereon:
generating a compensated fourth image by performing a second gray level map local compensation on the second image, the second gray level map local compensation being different than the first gray level map local compensation.

5. The method of claim 4, wherein a second value of a compensation factor of the second gray level map local compensation is greater than a first value of the compensation factor of the first gray level map local compensation.

6. The method of claim 5, wherein the second value is greater than the first value by a selected percentage.

7. The method of claim 1, wherein the generating a compensated third image includes generating an intensity distribution associated with a material of the mask.

8. The method of claim 7, wherein the generating a compensated third image includes determining an outlier of the intensity distribution and resampling a point in the second image that is associated with the outlier.

9. The method of claim 7, wherein the generating a compensated third image includes determining whether a point of the second image is associated with a number of materials that exceeds two.

10. The method of claim 9, wherein the generating a compensated third image includes, in response to the number exceeding two, removing gray scale information associated with the point from the compensated third image.

11. A method comprising:
generating a reference image by scanning a mask;
following the generating a reference image, generating a second image by scanning the mask;
generating a third image by performing a gray level map local compensation on the second image, the gray level map local compensation being via a transform function or a trained neural network;
generating a comparison result by comparing the third image with the reference image; and
based on the comparison result, determining whether the mask has a defect thereon.

12. The method of claim 11, wherein the gray level map local compensation is via a transform function, the method further comprising:
generating the trained neural network based on a plurality of historical scans of the mask.

13. The method of claim 12, wherein the generating the trained neural network includes training a neural network based on the plurality of historical scans of the mask and a second plurality of historical scans associated with a plurality of second masks other than the mask.

14. The method of claim 11, further comprising, in response to determining that the mask has a defect thereon:
generating a compensated fourth image by performing a second gray level map local compensation on the second image, the second gray level map local compensation being via a transform function or a trained neural network.

15. A system, comprising:
a detector operable to:
generate a first image by scanning a mask;
generate a second image by scanning the mask, the mask having been exposed to extreme ultraviolet (EUV) light in a lithography system prior to the generation of the second image by scanning a mask; and
control circuitry configured to:
generate a compensated third image by performing a gray level map local compensation on the second image, the gray level map local compensation being generated via a transform function or a trained neural network;
generate a comparison result by comparing the compensated third image with a reference image of the mask; and
based on the comparison result, determine whether the mask has a defect thereon.

16. The system of claim 15, wherein the processor, when executing the computer instructions to generate a compensated third image, executes the computer instructions to generate the compensated third image via a transform function.

17. The system of claim 16, wherein the transform function is
$$\frac{GL - {GL}_{mean}}{{GL}_{std} \cdot k} + {GL}_{mean} = {GL}_{new} ,$$
GL being a gray level at a position in the second image, GLₘₑₐₙ being an average of a plurality of gray levels at a plurality of positions in the second image, GL_{std} being a standard deviation of the plurality of gray levels, GL_{new} being a compensated gray level and k being a compensation factor, the compensation factor being a first value when generating the compensated third image.

18. The system of claim 17, wherein the processor is further configured to execute the computer instructions to:
in response to determining that the mask has a defect thereon, generate a compensated fourth image by performing a second gray level map local compensation on the second image, the second gray level map local compensation being via the transform function, the compensation factor when generating the compensated fourth image being a second value that exceeds the first value.

19. The system of claim 15, wherein the processor, when executing the computer instructions to generate a compensated third image, executes the computer instructions to generate the compensated third image via a trained neural network.

20. The system of claim 15, wherein the processor, when executing the computer instructions to generate a compensated third image, executes the computer instructions to generate the compensated third image by narrowing a histogram associated with the second image.
